(19) United States
(12) Patent Application Publication
(10) Pub. No.: US 2015/0034160 A1
(43) Pub. Date: Feb. 5, 2015

(54) THIN FILM PHOTOVOLTAIC DEVICE AND METHOD OF MAKING SAME

(71) Applicant: TSMC SOLAR LTD., Taichung City (TW)

(72) Inventors: Jyh-Lih WU, Tainan City (TW); Wen-Tsai YEN, Caotun Township (TW)

(73) Assignee: TSMC SOLAR LTD., Taichung City (TW)

(21) Appl. No.: 13/957,703

(22) Filed: Aug. 2, 2013

(51) Int. Cl. H01L 31/0352; H01L 31/18

(52) U.S. Cl. CPC H01L 31/035227; H01L 31/18
USPC 136/262; 136/252; 136/265; 136/264; 438/98

(57) ABSTRACT

A photovoltaic device includes a substrate; a back contact layer disposed on the substrate; an absorber layer for photo absorption disposed above the back contact layer; a buffer layer disposed above the absorber layer; a front contact layer disposed above the buffer layer; and a plasmonic nanostructured layer having a plurality of nano-particles, wherein the plasmonic nanostructured layer is between a topmost back contact layer surface and the absorber layer.

### BACKGROUND

Photovoltaic devices (also referred to as solar cells) absorb sun light and convert light energy into electricity. Photovoltaic devices and manufacturing methods therefore are continually evolving to provide higher conversion efficiency with thinner designs.

Thin film solar cells are based on one or more layers of thin films of photovoltaic materials deposited on a substrate. The film thickness of the photovoltaic materials ranges from several nanometers to tens of micrometers. Examples of such photovoltaic materials include cadmium telluride (CdTe), copper indium gallium selenide (CIGS) and amorphous silicon (α-Si). These materials function as light absorbers. A photovoltaic device can further comprise other thin films such as a buffer layer, a back contact layer, or a front contact layer.

### BRIEF DESCRIPTION OF DRAWINGS

Embodiments of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of a method of fabricating an exemplary photovoltaic device, according to an embodiment of the present disclosure.

FIG. 2 is a cross-sectional view of a portion of a photovoltaic device during fabrication, in accordance with one embodiment of the present disclosure.

FIG. 3 is a cross-sectional view of a portion of a photovoltaic device during fabrication, in accordance with another embodiment of the present disclosure.

FIG. 4 is a cross-sectional view of a portion of a photovoltaic device during fabrication, in accordance with yet another embodiment of the present disclosure.

FIG. 5 is a cross-sectional view of a portion of a photovoltaic device during fabrication, in accordance with yet another embodiment of the present disclosure.

FIG. 6 is a cross-sectional view of a portion of a photovoltaic device during fabrication, in accordance with yet another embodiment of the present disclosure.

### DETAILED DESCRIPTION

In the following description, specific details are set forth to provide a thorough understanding of embodiments of the present disclosure. However, one having ordinary skill in the art will recognize that embodiments of the disclosure can be practiced without these specific details. In some instances, well-known structures and processes are not described in detail to avoid unnecessarily obscuring embodiments of the present disclosure.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are intended for illustration.

This disclosure provides a photovoltaic device and a method for making the same. In such a photovoltaic device, a plasmonic nanostructured layer is used in combination with a back contact layer, an absorber layer, a buffer layer, and a front contact layer above the buffer layer to improve the light absorption efficiency of the absorber layer. Thus, the resulting photovoltaic device has improved photovoltaic efficiency. The disclosure also provides a method of making a photovoltaic device having a plasmonic nanostructured layer using wet process methods, such as spin coating and dip coating, for example. When preparing plasmonic nano-particles, usage of wet process methods avoid processing damages to the photovoltaic device that may result from conventional sputtering or thermal evaporation methods together with post annealing treatment.

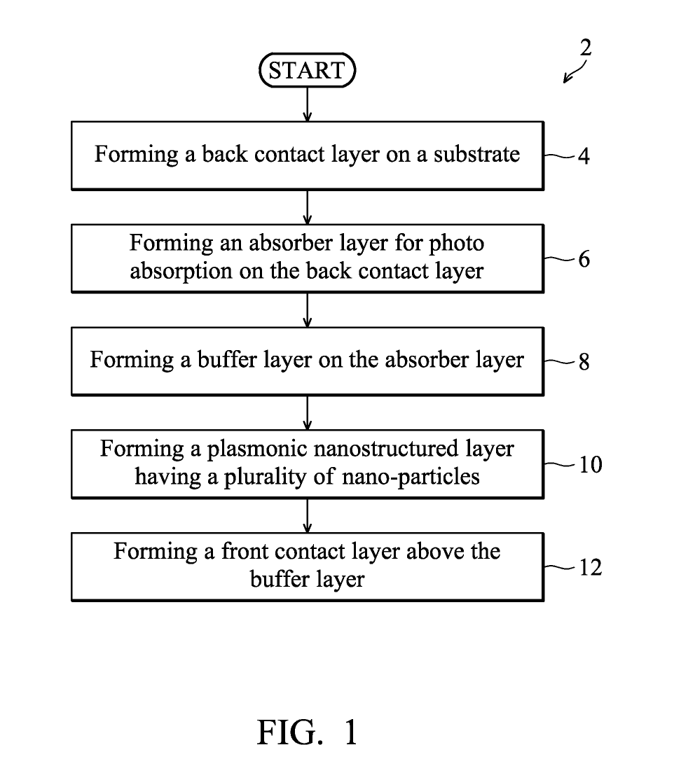

FIG. 1 is a flowchart of a method 2 for fabricating a photovoltaic device having a substrate, a back contact layer, an absorber layer, a buffer layer, a plasmonic nanostructured layer and a front contact layer, according to various aspects of the present disclosure. Referring to FIG. 1, the method 2 includes block 4, in which a back contact layer is formed on a substrate. The method 2 includes block 6, in which an absorber layer for photo absorption is formed on the back contact layer. The method 2 includes block 8, in which a buffer layer is formed on the absorber layer. The method 2 includes block 10, in which a plasmonic nanostructured layer is formed. The plasmonic nanostructured layer has a plurality of nano-particles. The method 2 includes block 12, in which a front contact layer is formed above the buffer layer.

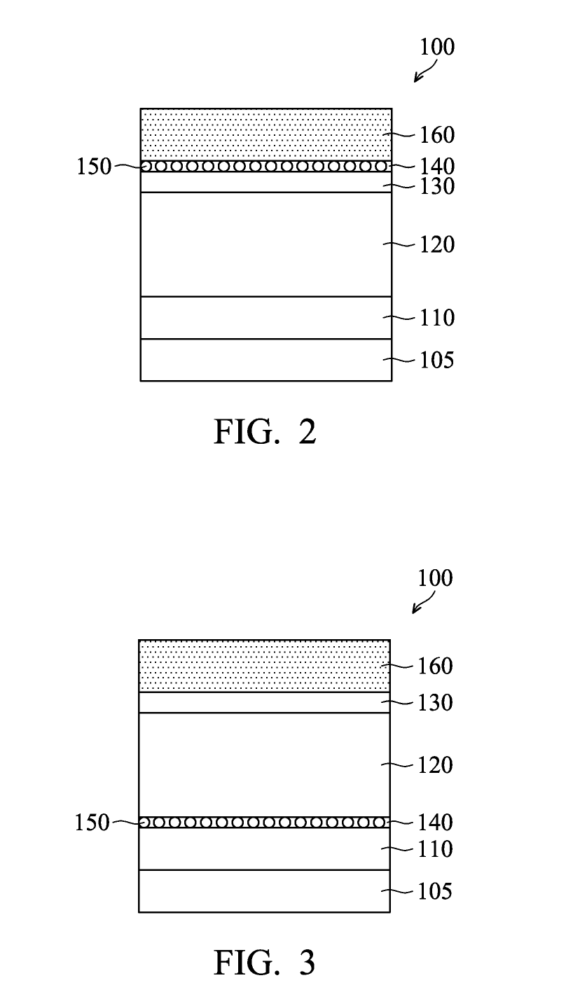

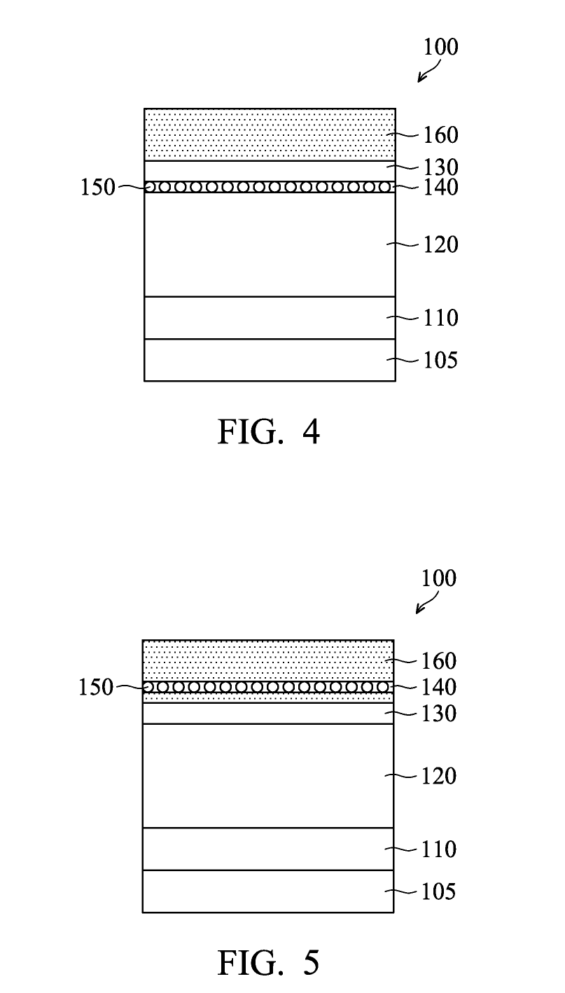

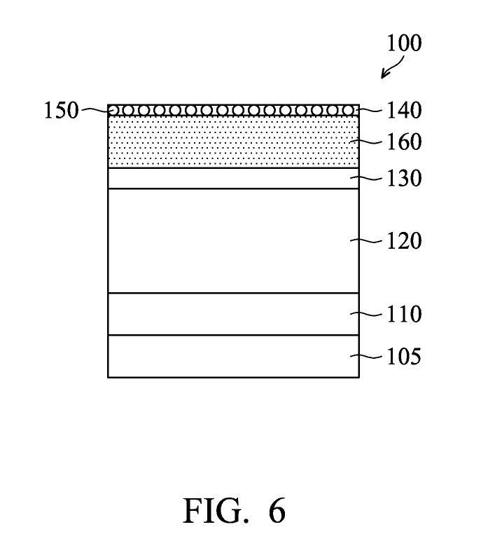

In various embodiments, the steps 4-12 are performed in respectively different sequences. In one embodiment, the steps are performed in the sequence 4-6-8-10-12, so that the plasmonic nanostructured layer is between the buffer layer and the front contact layer (described below with reference to FIG. 2). In another embodiment, the steps are performed in the sequence 4-10-6-8-12, so the plasmonic nanostructured layer is between the back contact layer and the absorber layer (described below with reference to FIG. 3). In another embodiment, the steps are performed in the sequence 4-6-10-8-12, so the plasmonic nanostructured layer is between the absorber layer and the buffer layer (described below with reference to FIG. 4). In another embodiment, the steps are performed in the sequence 4-6-8-12-10-12, so the plasmonic nanostructured layer is between two sub-layers of the front contact layer (described below with reference to FIG. 5). In another embodiment, the steps are performed in the sequence 4-6-8-12-10, so the plasmonic nanostructured layer is above the front contact layer (described below with reference to FIG. 6).

It is understood that additional processes (e.g., formation of scribe lines for the interconnect structure, not shown) may be performed before, during, and/or after the blocks 4-12 shown in FIG. 1 to complete the fabrication of the solar cell, but these additional processes are not discussed herein in detail for the sake of brevity.

FIGS. 2-6 are cross-sectional views of a portion of a photovoltaic device, fabricated by various embodiments of the method 2 of FIG. 1. It is understood that FIGS. 2-6 have been simplified for a better understanding of the inventive concepts of the present disclosure. It should be appreciated that the materials, geometries, dimensions, structures, and process parameters described herein are exemplary only, and are not intended to be, and should not be construed to be, limiting to the invention. Many alternatives and modifications will be apparent to those skilled in the art, once informed by the present disclosure.

Referring first to FIG. 2, the photovoltaic device 100 includes a substrate 105, a back contact layer 110, an absorber layer 120, a buffer layer 130 on the absorber layer 120, a plasmonic nanostructured layer 140, and a front contact layer 160 above the buffer layer.

Substrate 105 is made of any material suitable for thin film photovoltaic devices. Examples of materials suitable for use in substrate 105 include but are not limited to glass (such as soda lime glass), polymer (e.g., polyimide) film and metal foils (such as stainless steel). The film thickness of substrate 105 is in any suitable range, for example, in the range of about 0.1 mm to about 5 mm in some embodiments.

Back contact layer 110 can be selected based on the type of thin film photovoltaic device. In some embodiments, the back contact layer 110 is formed of molybdenum (Mo) above which a CIGS absorber layer 120 can be formed. In some embodiments, the Mo back contact layer 110 is formed by sputtering. Other embodiments include other suitable back contact materials, such as Pt, Au, Ag, Ni, or Cu, instead of Mo. For example, in some embodiments, a back contact layer of copper or nickel is provided, above which a cadmium telluride (CdTe) absorber layer can be formed. The thickness of the back contact layer 110 is on the order of nanometers or micrometers, for example, in the range of from about 100 nm to about 20 microns in some embodiments.

The absorber layer 120 for photon absorption is formed on the back contact layer 110. In some embodiments, the absorber layer 120 is a chalcopyrite-based absorber layer comprising Cu(In,Ga)Se₂ (CIGS), having a thickness of about 1 micrometer or more. In some embodiments, the absorber layer 120 is sputtered using a CuGa sputter target (not shown) and an indium-based sputtering target (not shown). In some other embodiments, the CuGa material is sputtered first to form one metal precursor layer and the indium-based material is next sputtered to form an indium-containing metal precursor layer on the CuGa metal precursor layer. In other embodiments, the CuGa material and indium-based material are sputtered simultaneously, or on an alternating basis.

In other embodiments, the absorber layer 120 comprises copper (Cu), gallium (Ga), indium (In), aluminum (Al), selenium (Se), selenide (S), and combinations thereof. In still other embodiments, the absorber layer 120 comprises different materials, such as CulnSe₂ (CIS), CuGaSe₂ (CGS), Cu(In,Ga)Se₂ (CIGS), Cu (In,Ga)(Se,S)₂ (CIGSS), CdTe and amorphous silicon. Other embodiments include still other absorber layer materials.

In yet another embodiment, the absorber layer 120 may be formed by a different technique that provides suitable uniformity of composition. For example, the Cu, In, Ga and Seₑ can be coevaporated and simultaneously delivered by chemical vapor deposition (CVD) followed by heating to a temperature in the range of 400 C to 600 C. In other embodiments, the Cu, In, and Ga are delivered first, and then the absorber layer is annealed in an Se atmosphere at a temperature in the range of 400 C to 600 C.

In other embodiments, the absorber layer 120 is formed using methods such as chemical vapor deposition, printing, electrodeposition or the like.

The absorber layer 120 has a thickness on the order of nanometers or micrometers, for example, from about 0.5 microns to about 10 microns. In some embodiments, the absorber layer 120 has a thickness from about 500 nm to about 2 microns.

The buffer layer 130 is formed above the absorber layer 120. In some embodiments, the buffer layer 130 can be one of the group consisting of CdS, ZnS, ZnSe, In₂S₃, In₂Se₃, and Zn₁₋ₓMgₓO, (e.g., ZnO). Other suitable buffer layer materials can be used. The thickness of the buffer layer 130 is on the order of nanometers, for example, in the range of from about 5 nm to about 100 nm in some embodiments.

Formation of the buffer layer 130 is achieved through a suitable process such as sputtering or chemical vapor deposition. For example, in some embodiments, the buffer layer 130 is a layer of CdS, ZnS or a mixture of CdS and ZnO, deposited through a hydrothermal reaction or chemical bath deposition (CBD) in a solution. For example, in some embodiments, a buffer layer 130 comprising a thin film of ZnS is formed above absorber layer 120 comprising CIGS. The buffer layer 130 is formed in an aqueous solution comprising ZnSO₄, ammonia and thiourea at 80 Celsius. A suitable solution comprises 0.16 M of ZnSO₄, 7.5 M of ammonia, and 0.6 M of thiourea in some embodiments.

Plasmonic nanostructured layer 140 comprising a plurality of nano-particles 150, such as metal nano-particles help the photovoltaic device 100 more efficiently absorb light. Silicon does not absorb light very well. For this reason, scattering more light across the surface of the substrate is desirable in order to increase the absorption. Metal nano-particles help to scatter the incoming light across the surface of the substrate. When light photons hit these metal nano-particles excited at their surface plasmon resonance, the light is scattered in many different directions. This allows the light to travel along the photovoltaic device 100 and bounce between the substrate 105 and the nano-particles 150 enabling the photovoltaic device 100 to absorb more light. Alternatively, excitation of particle surface plasmon resonance leads to local enhancement of the electromagnetic field surrounding the metal nano-particles. This phenomenon also increases the amount of photons harvested in the light absorber 120. The use of plasmonic nanostructured layer 140 in photovoltaic device 100 may obviate the need for thick absorber layers, especially for thin-film type solar cells.

Plasmonic nanostructured layer 140 can be formed on the photovoltaic device 100 through a suitable wet process, such as spin-coating, dip-coating, spray coating, doctor-blading, roll coating, screen coating, and the like. In one example, the Au nano-particle solutions were prepared by dissolving hydrogen tetrachloroaurate trihydrate (HAuC₁₄.3H₂O), cetyltrimethylammonium bromide (CTAB) and trisodium citrate (Na₃C₆H₅O₇.2H₂O) in pure water, followed by an annealing treatment at 110° C. The solutions were centrifuged at 6000 rpm for 20 min to remove the residual CTAB surfactant. After decanting the supernatant, the precipitate was re-dispersed in deionized water for another round of centrifugation. The resulting particle size of the Au nano-particles was in a range from 30-50 nm. The final concentration of Au nano-particles was 10¹²cm⁻³ for use. The plasmonic nanostructured layer 140 was prepared by spin-coating such an Au nano-particle solution on top of the buffer layer 130 at 600 RPM for 60 sec. The sample was then annealed at 110° C. for 30 min.

In some embodiments, plasmonic nanostructured layer 140 is formed by depositing the nano-particles 150 dispersed in a solution. For example, depositing plasmonic nanostructured layer 140 above the buffer layer 130 is performed in a solution comprising Au nano-particles in an electric field. In other embodiments, the plasmonic nanostructured layer 140 can be prepared by thermally annealing a metallic thin film (typically less than 20 nm); however, such processes may cause thermal damage to the device, thus degrading their electrical performances.

The nano-particles 150 for the plasmonic nanostructured layer 140 can be in a form such as nanotube, nanoplatelet, nanorod, nanoparticle, nanosheet or any other shapes or combinations thereof. The nano-particles 150 for the plasmonic nanostructured layer 140 can be made of carbon, graphite, metal or any other inorganic or organic conductive materials. In some embodiments, the nano-particles 150 in the plasmonic nanostructured layer 140 comprises metals such as, gold (Au), silver (Ag), copper (Cu), platinum (Pt), aluminum (Al), combinations thereof, and the like. In some embodiments, the nano-particles 150 in the plasmonic nanostructured layer 140 comprises dielectric particles, such as for example silicon dioxide (SiO₂), silicon nitride (Si₃N₄), or titanium dioxide (TiO₂). In still some other embodiments, the nano-particles 150 in the plasmonic nanostructured layer 140 comprises graphene nanoplatelets, carbon nanotubes (CNT) or silver nano-particles. According to one embodiment, carbon nanotubes can be dispersed in an aqueous solution comprising dispersant such as a surfactant. For example, in some embodiments, CNTs are dispersed in deionized water using a surfactant. Examples of suitable surfactants include but are not limited to butoxyethanol, tetramethyl-5-decyne-4, 7-diol, and alpha-(nonylphenyl)-omega-hydroxy-poly (oxy-1,2-ethanediyl). In some embodiments, the size of the nano-particles 150 is in a range from about 5 to about 250 nm.

The photovoltaic device 100 is dipped into the solution comprising dispersions of the nano-particles 150 and the dispersions of the nano-particles 150 are deposited onto a surface of the buffer layer 130.

In one embodiment, as shown in FIG. 2, the plasmonic nanostructured layer 140 is formed above the buffer layer 130. In another embodiment, as shown in FIG. 3, the plasmonic nanostructured layer 140 is formed above the back contact layer 110. The configuration in FIG. 3 may have performance advantages, because it obviates possible disadvantageous effects of backward scattering that may lead to photon loss. In yet another embodiment, as shown in FIG. 4, the plasmonic nanostructured layer 140 is formed above the absorber layer 120. In yet another embodiment, as shown in FIG. 5, the plasmonic nanostructured layer 140 is embedded between two sub-layers within the front contact layer 160. In yet another embodiment, as shown in FIG. 6, the plasmonic nanostructured layer 140 is formed above the front contact layer 160.

Referring again to FIG. 2, following the formation of the plasmonic nanostructured layer 140 above the buffer layer 130, the front contact layer 160 is formed on the photovoltaic device 100. The front contact layer 160 can comprise a single layer or multiple layers formed above the plasmonic nanostructured layer 140. Examples of suitable material for the front contact layer 160 include but are not limited to transparent conductive oxides such as indium tin oxide (ITO), fluorine-doped tin oxide (FTO), aluminum-doped zinc oxide (AZO), gallium doped ZnO (GZO), alumina and gallium co-doped ZnO (AGZO), boron doped ZnO (BZO), and any combinations thereof. A suitable material for the front contact layer 160 can also be a composite material comprising at least one of the transparent conductive oxide (TCO) and another conductive material, which does not significantly decrease electrical conductivity or optical transparency of the front contact layer 160. The thickness of the front contact layer 160 is in the order of nanometers or microns, for example in the range of from about 0.3 nm to about 2.5 μm in some embodiments.

Advantages of one or more embodiments of the present disclosure may include one or more of the following.

By avoiding use of sputtering or thermal evaporation methods in forming the plasmonic metallic nano-particle layer, one or more embodiments of the present invention avoids processing damages that might otherwise result to the solar cell.

By avoiding use of sputtering or thermal evaporation methods in forming the plasmonic metallic nano-particle layer, one or more embodiments of the present invention avoids the high costs associated with their uses.

Although particular examples are described above, the structures and methods described herein can be applied to a broad variety of thin film solar cells, such as a Si thin film solar cell; CIGS; solar cell of heterojunction with intrinsic thin layer (HIT solar cell); organic thin-film solar cell; or copper indium gallium diselenide (CuInGaSe₂) thin-film solar cell, and the like.

The present disclosure has described various exemplary embodiments. According to one embodiment, a photovoltaic device includes a substrate; a back contact layer disposed above the substrate; an absorber layer for photo absorption disposed above the back contact layer; a buffer layer disposed above the absorber layer; a front contact layer disposed above the buffer layer, and a plasmonic nanostructured layer having a plurality of nano-particles, wherein the plasmonic nanostructured layer is between a topmost back contact layer surface and the absorber layer.

In some embodiments, the absorber layer comprises at least one material selected from the group consisting of copper (Cu), gallium (Ga), indium (In), aluminum (Al), selenium (Se), or selenide (S), or combinations thereof

In some embodiments, the plurality of nano-particles include particles of different sizes.

In some embodiments, the plurality of nano-particles include particles of different shapes.

In some embodiments, the plurality of nano-particles include particles of different metal species.

In some embodiments, the plasmonic nanostructured layer includes particles in a form from the group consisting of nanotubes, nanoplatelets, nanorods, nanoparticles, nanosheets or combinations thereof.

In some embodiments, the plasmonic nanostructured layer includes graphene nanoplatelets, carbon nanotubes (CNT) or silver nano-particles.

In some embodiments, the nano-particles are metal particles selected from the group consisting of gold (Au), silver (Ag), platinum (Pt), aluminum (Al), or copper (Cu) or combinations thereof

In some embodiments, the size of the nano-particles is in a range from about 5 nm to about 250 nm.

In some embodiments, the plurality of nano-particles include particles of different sizes, particles of different shapes, and particles of different metal species.

According to another embodiment, a method of making a photovoltaic device, includes forming a back contact layer on a substrate. An absorber layer for photo absorption is formed on the back contact layer. A buffer layer is formed on the absorber layer. A plasmonic nanostructured layer having a plurality of nano-particles is formed by a wet process. A front contact layer is formed above the buffer layer.

In some embodiments, the plasmonic nanostructured layer is formed between the back contact layer and the absorber layer.

In some embodiments, the plasmonic nanostructured layer is formed above the absorber layer.

In some embodiments, the plasmonic nanostructured layer is formed above the buffer layer.

In some embodiments, the plasmonic nanostructured layer is formed within the front contact layer.

In some embodiments, the plasmonic nanostructured layer is formed above the front contact layer.

In some embodiments, the wet process includes chemical bath deposition, a spin coating process, a dip coating process, a doctor-blading process, a roll coating process, a screen coating process, or a printing process.

In some embodiments, the wet process includes spin coating the nanostructured layer on the buffer layer using a solution containing Au nano-particles having a particle size in a range from 30 nm to 50 nm, with a concentration of the Au nano-particles of about 10¹²cm⁻³.

In some embodiments, the method further comprises annealing the spin coated nanostructured layer.

In some embodiments, the wet process includes depositing nanoparticles dispersed in a solution comprising Au nano-particles, the depositing performed in an electric field.

In the preceding detailed description, specific exemplary embodiments have been described. It will, however, be apparent to a person of ordinary skill in the art that various modifications, structures, processes, and changes may be made thereto without departing from the broader spirit and scope of the present disclosure. The specification and drawings are, accordingly, to be regarded as illustrative and not restrictive. It is understood that embodiments of the present disclosure are capable of using various other combinations and environments and are capable of changes or modifications within the scope of the claims and their range of equivalents.

What is claimed is:

1. A photovoltaic device, comprising:
a substrate;
a back contact layer disposed above the substrate;
an absorber layer for photo absorption disposed above the back contact layer;
a buffer layer disposed above the absorber layer;
a front contact layer disposed above the buffer layer; and
a plasmonic nanostructured layer having a plurality of nano-particles, wherein the plasmonic nanostructured layer is between a topmost back contact layer surface and the absorber layer.

2. The photovoltaic device of claim 1, wherein the absorber layer comprises at least one material selected from the group consisting of copper (Cu), gallium (Ga), indium (In), aluminum (Al), selenium (Se), or selenide (S), or combinations thereof

3. The photovoltaic device of claim 1, wherein the plurality of nano-particles include particles of different sizes.

4. The photovoltaic device of claim 1, wherein the plurality of nano-particles include particles of different shapes.

5. The photovoltaic device of claim 1, wherein the plurality of nano-particles include particles of different metal species.

6. The photovoltaic device of claim 1, wherein the plasmonic nanostructured layer includes particles in a form from the group consisting of nanotubes, nanoplatelets, nanorods, nanoparticles, nanosheets or combinations thereof.

7. The photovoltaic device of claim 1, wherein the plasmonic nanostructured layer includes graphene nanoplatelets, carbon nanotubes (CNT) or silver nano-particles.

8. The photovoltaic device of claim 1, wherein the nano-particles are metal particles selected from the group consisting of gold (Au), silver (Ag), platinum (Pt), aluminum (Al), or copper (Cu) or combinations thereof.

9. The photovoltaic device of claim 1, wherein the size of the nano-particles is in a range from about 5 nm to about 250 nm.

10. The photovoltaic device of claim 1, wherein the plurality of nano-particles include particles of different sizes, particles of different shapes, and particles of different metal species.

11. A method of making a photovoltaic device, comprising:
forming a back contact layer on a substrate;
forming an absorber layer for photo absorption above the back contact layer;
forming a buffer layer above the absorber layer;
forming a plasmonic nanostructured layer having a plurality of nano-particles above the back contact layer by a wet process; and
forming a front contact layer above the buffer layer.

12. The method of claim 11, wherein the plasmonic nanostructured layer is formed between the back contact layer and the absorber layer.

13. The method of claim 11, wherein the plasmonic nanostructured layer is formed above the absorber layer.

14. The method of claim 11, wherein the plasmonic nanostructured layer is formed above the buffer layer.

15. The method of claim 11, wherein the plasmonic nanostructured layer is formed within the front contact layer.

16. The method of claim 11, wherein the plasmonic nanostructured layer is formed above the front contact layer.

17. The method of claim 11, wherein the wet process includes chemical bath deposition, a spin coating process, a dip coating process, a doctor-blading process, a roll coating process, a screen coating process, or a printing process.

18. The method of claim 17, wherein the wet process includes spin coating the nanostructured layer on the buffer layer using a solution containing Au nano-particles having a particle size in a range from 30 nm to 50 nm, with a concentration of the Au nano-particles of about 10¹²cm⁻³.

19. The method of claim 18, further comprising annealing the spin coated nanostructured layer.

20. The method of claim 17, wherein the wet process includes depositing nanoparticles dispersed in a solution comprising Au nano-particles, the depositing performed in an electric field.
